(19) United States
(12) Patent Application Publication
(10) Pub. No.: US 2010/0240164 A1
(43) Pub. Date: Sep. 23, 2010

(54) RADIATION DETECTOR MANUFACTURING METHOD

(75) Inventors: Katsuhiro KOHDA, Ashigarakami-gun (JP); Naoharu KIYOTO, Ashigarakami-gun (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM CORPORATION, Tokyo (JP)

(21) Appl. No.: 12/725,042

(22) Filed: Mar. 16, 2010

(30) Foreign Application Priority Data
Mar. 17, 2009 (JP) 2009-063765

(51) Int. Cl. H01L 31/18

(52) U.S. Cl. 438/57; 257/E31.001

(57) ABSTRACT

A coating film is formed by applying, on a tentative support, a dispersion solution in which at least an inorganic semiconductor particle and a binder are dispersed. Then, a radiation photoconductive layer is formed by subjecting the coating film to thermal compression, and the radiation photoconductive layer is joined to an active matrix layer in which multiple switching elements are arranged. This allows the radiation photoconductive layer to generate a charge in response to radiation of an electromagnetic wave representing image information and to be arranged such that the charge is read out by the active matrix layer.

### BACKGROUND OF THE INVENTION

1. Field of the Invention

The present invention relates to a radiation detector preferably applied to a radiography system, such as an X-ray machine, and more specifically to a method for manufacturing a direct conversion radiation detector.

2. Description of the Related Art

Today, in the filed of X-ray (radiation) radiography for medical diagnosis, various types of X-ray machines that use a radiation detector (with a main portion formed of semiconductor) as an X-ray image information recording means and detect X-rays transmitted through a subject with the radiation detector in order to obtain an image signal representing an X-ray image of the subject are proposed and put into practical use.

Also, for the radiation detectors used in such machines, various types are proposed. For example, from the aspect of charge generation process in which X-rays are converted to charges, the following are known. That is, a radiation detector of optical conversion type (indirect conversion type) in which signal charges obtained by detecting fluorescence emitted from a phosphor exposed to X-ray radiation with a photoconductive layer are tentatively stored in a storage section, and the stored charges are converted to image signals (electrical signals) and outputted, and a radiation detector of direct conversion type in which signal charges generated in a photoconductive layer by X-ray radiation are collected by a charge collection electrode to tentatively store in a storage section and the stored charges are converted to electrical signals and outputted. Direct conversion radiation detectors include a radiation photoconductive layer and an electrode as major components.

From the aspect of charge readout process in which stored charges are read out, an optical readout type in which the charges are read out by emitting readout light (readout electromagnetic wave) onto the detector and a TFT readout type in which charges are read out by scan driving TFTs (thin film transistors) connected to the storage section are known.

Among those described above, the direct conversion TFT readout type (simply, “TFT type”) is used widely as medical diagnostic devices because it does not require a scintillator layer for tentatively converting radiation to light and has excellent image sharpness. In the TFT type, the radiation photoconductive layer is generally formed of amorphous selenium (a-Se), because of its high dark resistance and excellent response time, as described, for example, in U.S. Pat. No. 5,319,206 and Japanese Unexamined Patent Publication No. 2001-320035.

In the mean time, a-Se has a problem that the thermal stability is not sufficient and crystallization is likely to occur at a temperature above 50° C., whereby the sensitivity is degraded so that certain restrictions exist on the use. Based on this viewpoint, Bi₁₂MO₂₀ (M is Si, Ge, or Ti) which is stable and has a high X-ray absorption is described in U.S. Patent Application Publication No. 20050214581 as a substitute for a-Se. Each of the radiation photoconductive layers described in U.S. Pat. No. 5,319,206, Japanese Unexamined Patent Publication No. 2001-320035, and U.S. Patent Application Publication No. 20050214581 is formed by vapor phase growth or sintering and has an advantage that it has high charge collection efficiency.

In order to produce radiation photoconductive layers by vapor phase growth or sintering, the layers need to be produced one by one, taking a long time, whereby the cost is increased. Further, in the joining of TFTs, the TFT needs to be joined on a pixel by pixel basis. U.S. Pat. No. 6,242,746 describes a method for bonding a radiation photoconductive layer to TFTs with a conductive adhesive in which radiation photoconductive layer is bonded to a corresponding TFT electrode of each pixel. It is difficult, however, to perform the bonding without any positional displacement over the entire pixels, resulting in a degraded yield rate and an increased cost.

As a low cost method for manufacturing a radiation photoconductive layer, a method in which a photoconductive layer is formed by dispersing inorganic semiconductor particles that induce radiation photoconductivity in an organic solvent using a polymer as a binder, and applying and drying the solution is known. For example, Japanese Unexamined Patent Publication No. 11 (1999)-211832 discloses an example in which an X-ray photoconductive layer is directly applied on a substrate having TFTs. Further, U.S. Patent Application Publication No. 20050118527 describes a method for manufacturing an X-ray photoconductive layer using HgI₂ with a polymer as a binder. Still further, U.S. Patent Application Publication No. 20070122543 describes a method for manufacturing an X-ray photoconductive layer using PbO with a polyimide as a binder.

The radiation photoconductive layers produced by the coating methods described above, however, have a low filling rate of inorganic semiconductor particles that induce radiation photoconductivity because the layers are formed simply by applying and drying the dispersion solutions, thereby posing a problem that it has low X-ray absorption in comparison with radiation photoconductive layers formed by vapor phase growth or sintering. In order to increase the filling rate in a coating method, thermal compression methods, such as calendaring, are conceivable, if the photoconductive layer is subjected to thermal compression after TFTs are attached, a TFT element or a glass substrate may be damaged. As such, the thermal compression may be performed only at a low temperature or pressure, resulting in a low filling rate.

That is, heretofore, it has been the circumstance that one must select a coating method if the priority is on the simplicity of manufacturing process and cost at the expense of performance of a radiation photoconductive layer, or a vapor phase growth or sintering method if the priority is on the performance of the radiation photoconductive layer at the expense of complexity of manufacturing process and cost.

The present invention has been developed in view of the circumstances described above, and it is an object of the present invention to provide a method for manufacturing a radiation detector based on a coating method and capable of increasing the filling rate of inorganic semiconductor particles that induce radiation photoconductivity.

### SUMMARY OF THE INVENTION

A radiation detector manufacturing method of the present invention is a method for manufacturing a radiation detector having an active matrix layer in which multiple switching elements are arranged and a radiation photoconductive layer that generates a charge in response to radiation of an electromagnetic wave representing image information and arranged such that the charge is read out by the active matrix layer, the method including the steps of:

forming a coating film by applying, on a tentative support, a dispersion solution in which at least an inorganic semiconductor particle and a binder are dispersed;

forming the radiation photoconductive layer by subjecting the coating film to thermal compression; and

joining the radiation photoconductive layer to the active matrix layer.

Preferably, a pressing pressure at the time of the thermal compression is in the range from 100 to 2000 kg/cm². Preferably, the dispersion solution includes a charge transport material. Preferably, an undercoating layer is provided on the thermo-compressed radiation photoconductive layer or the radiation photoconductive layer is joined to the active matrix layer after an undercoating layer is provided on the active matrix layer. Preferably, the undercoating layer is a hole injection blocking layer.

The radiation detector manufacturing method of the present invention is a method for manufacturing a radiation detector having an active matrix layer in which multiple switching elements are arranged and a radiation photoconductive layer that generates a charge in response to radiation of an electromagnetic wave representing image information and arranged such that the charge is read out by the active matrix layer, in which a coating film is formed by applying, on a tentative support, a dispersion solution in which at least an inorganic semiconductor particle and a binder are dispersed, then the radiation photoconductive layer is formed by subjecting the coating film to thermal compression, and the radiation photoconductive layer is joined to the active matrix layer. This allows a radiation photoconductive layer produced even by a coating method to have a high filling rate of inorganic semiconductor particles, whereby radiation absorption may be increased. Further, the radiation photoconductive layer is formed by subjecting the coating film to thermal compression, so that the probability that the inorganic semiconductor particles are electrically connected to each other is increased and the amount of charges reaching the electrode is increased, resulting in an improved image quality.

The conventional coating method in which coating is performed directly on an active matrix layer needs to perform the application and drying one by one, which takes time. Further, in the direct coating method, when the coating is failed the active matrix must also be discarded, whereby the overall yield rate of the product is significantly reduced. Whereas, in the radiation detector manufacturing method of the present invention, a large number of radiation photoconductive layers may be manufactured at a time by continuously applying and drying for a large number of the layers. Furthermore, each of the radiation photoconductive layers may be inspected after cutting into each layer and before joining to the active matrix layer, whereby the overall yield rate of the product may be improved.

### BRIEF DESCRIPTION OF THE DRAWINGS

FIG. 1 illustrates a radiation detector manufacturing process according to an embodiment of the present invention.

FIG. 2 illustrates a radiation detector manufacturing process according to another embodiment of the present invention.

FIG. 3 is a schematic sectional view of a BMO particle manufacturing system with a shearing agitator.

FIG. 4 is a graph illustrating the relationship between the pressing pressure and filling rate.

FIG. 5 is a graph illustrating the relationship between the filling rate and collected charge amount.

### DESCRIPTION OF THE PREFERRED EMBODIMENTS

Two types of radiation detectors are available. One of which is a direct conversion type in which radiation is directly converted to charges and stored, and the other of which is an indirect conversion type in which radiation is first converted to light by a scintillator, such as CsI, and then the light is converted to charges by an amorphous-Si photodiode. The radiation detector manufacturing method of the present invention may be applied to a method for manufacturing the former direct conversion type radiation detectors. Further, the radiation detector manufacturing method of the present invention may be applied to a method for manufacturing the following radiation detectors of two readout types: a detector in which charges generated by the emission of radiation are stored in capacitors and the charges stored in the capacitors are transferred to an external circuit by ON/OFF switching an electric switch, such as a thin film transistor (TFT) or the like, with respect to each pixel; and a detector in which MOS transistors are arranged on a silicon substrate in an array and voltages generated by accumulated charges are transferred to an external circuit. As for the radiation, γ ray and a ray may be used, in addition to X-ray.

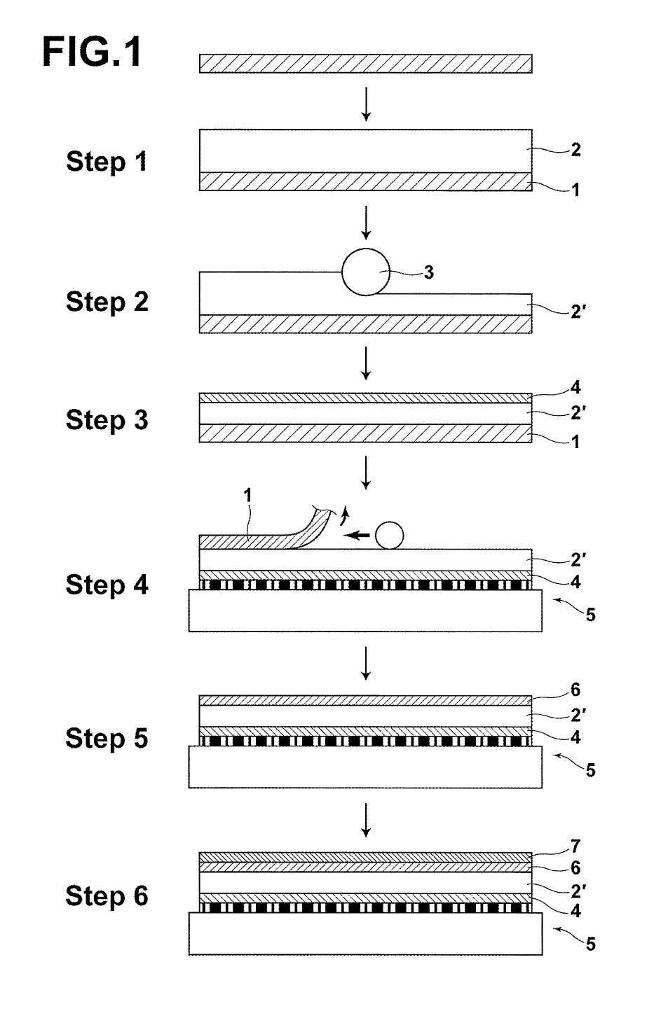

Hereinafter, a radiation detector manufacturing method of the present invention will be described with reference to the accompanying drawings. FIG. 1 illustrates a radiation detector manufacturing process according to an embodiment of the present invention. The process starts with providing a dispersion solution. The dispersion solution is a solution having therein at least inorganic semiconductor particles and a binder. The dispersion solution is coated on tentative support 1 to form coated film 2 (Step 1). Coated film 2 may be formed by any known coating method, such as dip method, spraying, bar coating, giesser coating, or the like.

Coated film 2 is subjected to hot air drying and then to thermal compression with calender roller 3 (Step 2). The thermal compression allows coated film 2 to have a high filling rate of the inorganic semiconductor particles and to be smoothed in the surface. The thermal compression may be performed with a planar press machine or the like other than with calender roller 2. The pressing pressure at the time of thermal compression varies with the type of the inorganic semiconductor particles and binder, but preferably in the range from 100 to 2000 kg/cm², and more preferably in the range from 200 to 1000 kg/cm². When the pressing pressure is below 100 kg/cm², it is difficult to increase the filling rate for certain types of inorganic semiconductor particles, while if it is higher than 2000 kg/cm², certain types of inorganic semiconductor particles may be destroyed (increased defects, crystal break, and the like), which is undesirable since the amount of charges generated in the film by radiation and the conductivity of the film are degraded.

Next, hole injection blocking layer 4 is formed on the compression processed coated film (radiation photoconductive layer) 2′ and dried by hot air drying (Step 3). Then, radiation photoconductive layer 2′ is placed on active matrix layer 5 with the side opposite to tentative support 1, i.e., on the side of undercoating layer 4 facing to active matrix layer 5 and tentative support 1 is peeled off. After tentative support 1 is peeled off, active matrix layer 5 and undercoating layer 4 on radiation photoconductive layer 2′ are joined by a laminator (Step 4). The lamination is performed at a low temperature and a low pressure that do not destroy active matrix layer 5. A larger portion of the binder component tends to collect on the side opposite to tentative support 1 and by arranging the side toward active matrix layer 5, the adhesion with active matrix layer 5 may be increased.

As radiation photoconductive layer 2′ is a coated film, the inorganic semiconductor particles of radiation photoconductive layer 2′ are electrically joined to active matrix layer 5 by the joining. This eliminates the need to electrically connect to a corresponding TFT electrode of each pixel, whereby the manufacturing cost may be reduced.

Note that radiation photoconductive layer 2′ is joined while tentative support is being peeled off, but radiation photoconductive layer 2′ may be joined to active matrix layer 5 with the side of undercoating layer 4 facing to active matrix layer 5 after tentative support 1 is completely peeled off from radiation photoconductive layer 2′. After the joining, electron injection blocking layer 6 is formed on radiation photoconductive layer 2′ by coating (Step 5) and upper electrode 7 is provided after electron injection blocking layer 6 is dried (Step 6).

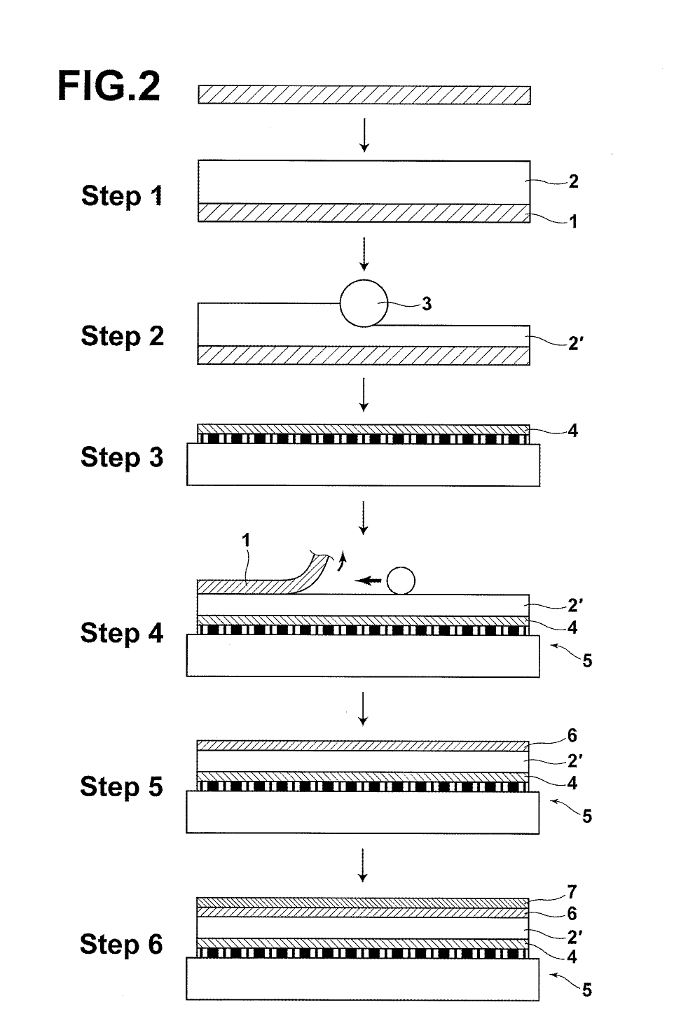

FIG. 1 illustrates a case in which undercoating layer 4 is formed on radiation photoconductive layer 2′ by coating, but undercoating layer 4 may be formed on active matrix layer 5. A manufacturing process of this embodiment will be described using FIG. 2. In FIG. 2, components identical to those of FIG. 1 are given the same reference numerals and will not be elaborated upon further here unless otherwise specifically required. As illustrated in FIG. 2, undercoating layer 4 is formed on active matrix layer 5 and dried by hot air drying (Step 3). Then, radiation photoconductive layer 2′ provided in Step 2 is placed on undercoating layer 4 with the side opposite to the side of tentative support 1 facing to active matrix layer 5 and tentative support 1 is peeled off. After tentative support 1 is peeled off, radiation photoconductive layer 2′ and undercoating layer 4 provided on active matrix layer 5 are joined by a laminator (Step 4).

In each of the embodiments above, the description has been made of a case in which the radiation photoconductive layer is joined to the active matrix layer with the side opposite to the side of the tentative support facing to the active matrix layer. But the joining is not necessarily made with this orientation, and the joining may be made with the reverse orientation, i.e., joining the radiation photoconductive layer to active matrix layer with the side of the tentative support facing to the active matrix layer. When the undercoating layer is provided on the active matrix layer, in particular, the tentative support may be peeled off first and then the radiation photoconductive layer may be joined to the active matrix layer with the side of the tentative support facing to the active matrix layer.

The tentative support used in the radiation image manufacturing method of the present invention may be formed, for example, of glass, metal plate, any of various materials used as a support of an intensifying paper (or intensifying screen) in the conventional radiography, or any known material used as a support of a radiation image conversion panel. More specifically, films of plastic materials, such as acetylcellulose, polyester, polyethylene terephthalate, polyamide, polyimide, triacetate, polycarbonate, and the like; aluminum foils; metal sheets, such as aluminum alloy foil; ordinary papers; baryta papers; resin coated papers; pigment papers, such as a paper containing a pigment of titanium dioxide and the like; papers sized with polyvinyl alcohol and the like; ceramics plates or sheets, such as alumina, zirconia, magnesia, and titania; and the like may be cited.

As described above, the coated film is formed by applying solution of dispersed inorganic semiconductor particles on the tentative support and peeling off from the tentative support after dried. It is, therefore, preferable that a release agent is applied on the tentative support in advance to facilitate the peeling. The coated film of the release agent may be formed, for example, by applying a toluene solution dissolving dimethyl silicone on the tentative support by spin coating or using a doctor blade and drying the applied solution.

There is not any specific restriction on the inorganic semiconductor particles used in the radiation detector manufacturing method of the present invention. But those with elements of small atomic number and a high density are preferably used. For example, inorganic semiconductor particles with a major element of high atomic number and high density, such as CdTe (density of 5.9 g/cm³), Zn doped CdTe (CdZnTe, hereinafter, also CZT), HgI₂ (density of 6.4 g/cm³), PbI₂ (density of 6.2 g/cm³), PbO (density of 9.8 g/cm³), Bi₁₂MO₂₀ (M is at least one of Si, Ge, and Ti), BiI₂, and the like may be used. Among them, Bi₁₂MO₂₀ is preferable because it has a high stability and a high radiation absorption rate.

As the binder, the following are preferably used, namely, polystyrene, polyolefin, polyurethane, linear polyester, polyamide, polybutadiene, ethylene vinyl acetate, polyvinyl chloride, natural rubber, fluoro rubber, polyisoprene, chlorinated polyethylene, styrene-butadiene rubber, silicon rubber, polycarbonate, polyvinyl butyral, chloroethene, and the like. The above cited binders generally have softening temperatures or melting points in the range from 30 to 300° C. It is preferable to select a binder having a softening temperature or melting point in the range from 30 to 200° C., and more preferably in the range from 30 to 150° C.

A solvent may be used in the dispersion solution to prepare an application liquid. Preferable solvents include alcohols, such as methanol, ethanol, propanol, butanol, and the like; chlorinated hydrocarbons, such as methylene chloride, ethylene chloride, chlorobenzene, dichlorobenzene, and the like; ketones, such as acetone, methyl ethyl ketone, methyl isobutyl ketone, and the like; lower alcohol esters of fatty acids, such as methyl acetate, ethyl acetate, butyl acetate, and the like; ethers, such as dioxane, ethylene glycol monoethyl ether, ethylene glycol monomethyl ether, and the like; toluenes; and the like. These solvents may be used singly or in combination as appropriate.

The dispersion solution is a solution in which at least inorganic semiconductor particles and a binder are dispersed, and it is preferable that a charge transport material is added to the solution in order to allow both electrons and holes flow smoothly through the radiation photoconductive layer. Preferable charge transport materials include polyvinyl carbazole, polyvinylpyrene, polyvinylanthracene, polythiophene, Alq₃ (tris(8-hydroxyquinoline) aluminum), polyphenylenevinylene, polyalkylthiophene, triphenylene, DCM (4-(dicyanomethyl)-2-methyl-6-(4-dimethylaminostyryl)-4-H-pyrane, rubrene, CBP (4,4′-Bis (carbazol-9-yl)-biphenyl), BCP(basocuproine), m-MTDATA (4,4′,4″-tris(N,N-phenyl-m-tolylamino) triphenylamine), TPD (N,N′-diphenyl-N,N′-bis(3-methylphenyl)-(1,1′-biphenyl)-4,4′-diamine, and the like.

For the undercoating layer, polymers identical to those for the binder described above may be used. The material may be adjusted to an appropriate viscosity with one of the solvent described above, and thinly applied using doctor blade, wire bar, or spin coat, whereby semiconductor particles in the photoconductive layer are brought into contact with TFT electrodes and charges generated in the photoconductive layer by X-rays may be transferred to the TFT electrodes.

Among various types of inorganic semiconductor particles, when Bi₁₂MO₂₀ particles are used, electrons are the majority carrier and a voltage is applied in a direction so that electrons reach TFT electrodes. Thus, the TFT electrodes are set to positive (+), and if holes are injected from the TFT electrodes, dark current is increased. Therefore, it is preferable that an electron transport material for blocking holes is included in the undercoating layer. In actuality, for example, this can be realized by mixing an electron transport material in the undercoating solution described above.

Preferable electron transport materials include fullerenes (C₆₀, C₇₀, and the like), PBD (2-(4-Biphenyl)-5-phenyl-1,3,4-oxadiazole), 2-(4-Bromophenyl)-5-phenyl-1,3,4-oxadiazole, 2,1,3-Benzoxadiazole-5-carboxylic, 2-(4-tert-Butylphenyl)-5-(4-biphenyl)-1,3,4-oxadiazole, PPD (2,5-Diphenyl-1,3,4-oxadiazole), BAO (2,5-Bis(4-aminophenyl)-1,3,4-oxadiazole, 5-(4-Methoxyphenyl)-1,3,4-oxadiazole-2-thiol, 5-(4-Pyridyl)-1,3,4-oxadiazole-2-thiol, 5-Phenyl-1,3,4-oxadiazole-2-thiol, 5-(4-Methylphenyl)-1,3,4-oxadiazole-2-thiol, and the like. Hereinafter, the radiation detector manufacturing method of the present invention will be described further in detail using Examples.

### Example 1

### Manufacture of Bi₁₂SiO₂₀ Particles

482 g of bismuth nitrate pentahydrate (Bi (NO₃)₃.5H₂O, purity of 99.9%) was dissolved in 800 ml of IN nitric acid solution and water was added to prepare 1000 ml of adding solution “a”. Separately, 12.9 g of potassium metasilicate and 325 g of potassium hydroxide were dissolved in water to prepare 1000 ml of adding solution “b”. In addition, 7.7 g of potassium metasilicate and 281 g of potassium hydroxide were dissolved in water to prepare 5000 ml of mother liquor “P”.

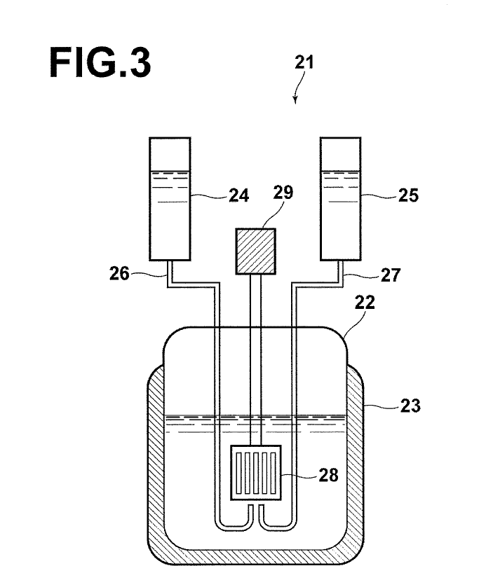

Bi₁₂SiO₂₀ particles were manufactured using manufacturing system 21 with a shearing agitator shown in FIG. 3. Manufacturing system 21 shown in FIG. 3 includes reaction vessel 22 for agitating and mixing the alkali solution and bismuth compound to induce reaction, jacket 23 for heating and maintaining reaction vessel hot, solution tank 24 to which the alkali solution is introduced, solution tank 25 to which the bismuth compound solution is introduced, solution flow paths 26 and 27 for supplying the alkali solution and bismuth compound solution to reaction vessel 22 from solution tanks 24 and 25 respectively, shearing agitator 28 for agitating the solution in reaction vessel 22, and motor 29 for driving shearing agitator 28.

Mother liquor “P” was introduced into reaction vessel 22 of manufacturing system 21, and adding solutions “a” and “b” were introduced into solution tanks 24 and 25 respectively. Mother liquor “P” was heated to 90° C. by jacket 23. The rotational speed of motor 29 was set at 4000 rpm and mother liquor “P” was agitated by shearing agitator 28. Here, the circumferential velocity of the agitating blade was 3.5 m/min. While maintaining this state, adding solutions “a” and “b” were added to reaction vessel 22 from solution tanks 24 and 25 respectively at a rate of 20 ml/min. After completion of the addition, the agitation was continued further for 30 minutes. Then the mixture was cooled down to room temperature and a faint yellow dispersed substance was filtered. After the filtration, the filtered substance was washed three times with 0.1N potassium hydroxide solution, then washed several times with water, and finally subjected to ethanol washing, whereby Bi₁₂SiO₂₀ particles were obtained.

### (Preparation of Dispersion Solution)

A binder solution was prepared by mixing 5 g of linear polyester resin (Bairon 300, Toyobo Co., Ltd.) with 20 g of methyl ethyl ketone and agitating the mixture until the linear polyester resin was completely dissolved. Then, a Bi₁₂SiO₂₀ dispersion solution was prepared by putting 100 g of particles in the binder solution and dispersing the particles for 20 minutes by a homogenizer dispersion system with a blade revolution speed of 3000 rev/sec.

### (Formation of Bi₁₂SiO₂₀ Dispersion Coating Film)

Polyethylene terephthalate film of 250 μm thick having a silicon release agent applied thereon is placed and fixed on a flatly placed glass plate with the release agent side up. Then the Bi₁₂SiO₂₀ dispersion solution was dropped on the film and coated using a doctor blade. After drying at room temperature for one hour, the coating on the glass plate was put in a drying oven with the glass plate and subjected to hot air drying at 100° C. for 30 minutes. In this way, a Bi₁₂SiO₂₀ dispersion coating film of 300 μm thick was formed on the polyethylene terephthalate film.

### (Thermal Compression)

The glass plate was removed, and the polyethylene terephthalate film with the Bi₁₂SiO₂₀ dispersion coating film formed thereon was subjected to heat pressing (hot pressing). The heat pressing was performed for one minute with a pressing plate temperature set to 150° C. and varying pressures. From the force exerted on the pressing machine (kilogram weight) and the area of the coating film (cm²), the pressure converted to a unit area of the coating film was 210 kg/cm².

### (Joining to TFT Substrate)

The Bi₁₂SiO₂₀ film peeled from the polyethylene terephthalate film was placed on a glass substrate, having TFTs arranged in a two-dimensional matrix, on the TFT electrode side. Here, the Bi₁₂SiO₂₀ film was placed on the glass substrate with the side opposite to the side which had contacted the polyethylene terephthalate film was brought into contact with the TFT electrode side. Next, the stacked body of the Bi₁₂SiO₂₀ film and glass substrate was inserted between silicon resin laminating rollers heated to 150° C. and passed through the rollers at a speed of 0.3 cm/sec, whereby a joined body of the TFTs and Bi₁₂SiO₂₀ film.

### (Provision of Upper Electrode)

An Au electrode was provided over the upper surface of the Bi₁₂SiO₂₀ film joined to the TFTs with a thickness of 1 nm using an evaporator, whereby the manufacture of a radiation detector was completed.

### Example 2

A radiation detector was provided in a manner similar to that of Example 1, except that the same type of resin as that of the binder (Bairon 300) was prepared as an undercoating solution and applied on the electrode side of TFTs with glass as an undercoating layer with a thickness of 0.1 μm using spin coating before the step of (Joining to TFT Substrate).

### Example 3

A radiation detector was provided in a manner similar to that of Example 2, except that fullerene C60 was added to the undercoating solution.

### Example 4

A radiation detector was provided in a manner similar to that of Example 1, except that HgI₂ particles were used instead of Bi₁₂SiO₂₀ particles. The HgI₂ particles were obtained by mixing and agitating 0.6M of HgCl₂ and 1.2M of KI water solution to obtain an HgI₂ deposition, washing the deposition with deionized water to remove an unwanted component, filtering the deposition to remove water and drying it on a pad, and screening the dried HgI₂ particles with a 20 μm screen to remove particles of large sizes and aggregates.

### Example 5

A radiation detector was provided in a manner similar to that of Example 1, except that PbI₂ particles were used instead of Bi₁₂SiO₂₀ particles. The PbI₂ particles were obtained by mixing and agitating 0.3M of Pb (NO₃)₂ water solution and 0.6M of KI water solution to obtain an PbI₂ deposition, washing the deposition with deionized water to remove an unwanted component, filtering the deposition to remove water and drying it on a pad, and screening the dried PbI₂ particles with a 20 μm screen to remove particles of large sizes and aggregates.

### Comparative Example 1

A radiation detector was provided in a manner similar to that of Example 1, except that the step of (Thermal Compression) was omitted.

### Comparative Example 2

A radiation detector was provided in a manner similar to that of Example 2, except that the step of (Thermal Compression) was omitted.

### Comparative Example 3

A radiation detector was provided in a manner similar to that of Example 4, except that the step of (Thermal Compression) was omitted.

### Comparative Example 4

A radiation detector was provided in a manner similar to that of Example 5, except that the step of (Thermal Compression) was omitted.

### (Filling Rate Measurement)

A spatial filling rate of Bi₁₂SiO₂₀, HgI₂, or PbI₂ particles in each of the radiation photoconductive layers produced in Examples 1 to 5 and Comparative Examples 1 to 4 was obtained by the formula below.

Filling Rate=aW/(1+a)SLd

where,

a: weight (g) of (Bi₁₂SiO₂₀, HgI₂, or PbI₂)/weight (g) of binder at the time of blending

W: weight of radiation photoconductive layer (g)

S: area of radiation photoconductive layer (cm²)

L: film thickness of radiation photoconductive layer (cm)

d: density of Bi₁₂SiO₂₀, HgI₂, or PbI₂ (g/cm²)

### (Measurement of Collected Charge Amounts)

A 10 mR X-ray (tungsten X-ray tube voltage of 80 kV) was emitted to the detection unit of each of radiation detectors produced in Examples 1 to 5 and Comparative Examples 1 to 4 for 0.1 seconds after a voltage of 3000V is applied between the electrodes. The optical current flowed between the electrodes was converted to a voltage value by a current amplifier and observed with a digital oscilloscope. Based on a current vs time curve obtained, the range corresponding to the X-ray emission time was integrated and converted to a collected charge amount per unit area of the radiation photoconductive layer.
The results are shown in Table 1.

TABLE 1

| | Inorganic | Pressing | | Collected |
|---|---|---|---|---|
| | Semiconductor | pressure | Filling Rate | Charge |
| | Particles | (kg/cm²) | (%) | Amount |
| EG 1 | Bi₁₂SiO₂₀ | 210 | 41 | 2800 |
| EG 2 | Bi₁₂SiO₂₀ | 210 | 40 | 2650 |
| EG 3 | Bi₁₂SiO₂₀ | 210 | 41 | 3600 |
| EG 4 | HgI₂ | 210 | 54 | 5100 |
| EG 5 | PbI₂ | 210 | 46 | 4000 |
| C/E 1 | Bi₁₂SiO₂₀ | — | 35 | 220 |
| C/E 2 | Bi₁₂SiO₂₀ | — | 34 | 290 |
| C/E 3 | HgI₂ | — | 40 | 2800 |
| C/E 4 | PbI₂ | — | 35 | 2100 |

As is clear from Table 1, the radiation detector manufacturing method of the present invention may provide a radiation photoconductive layer having a high filling rate, and a collected charge amount of a little over ten times as much as that of the comparative examples is obtained for Bi₁₂SiO₂₀ and about two times as much as that of the comparative examples is obtained for PbI₂ and HgI₂.

### Example 6

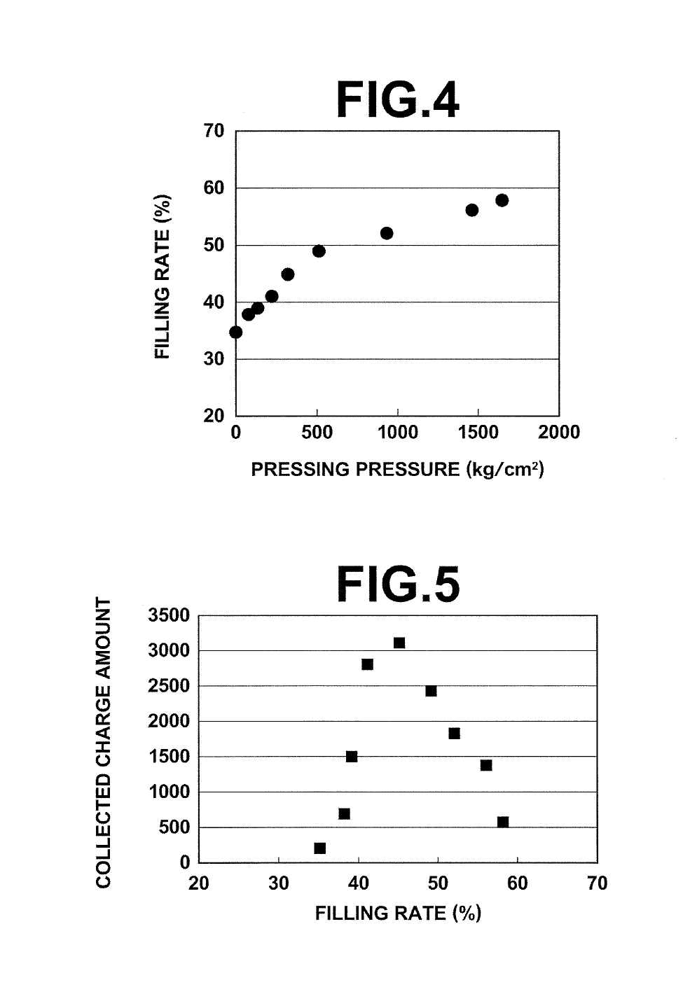

In Example 1, the pressing pressure at the time of thermal compression was changed to various values as shown in Table 2 and the filling rate and collected charge amount at each pressure were measured in the same manner as described above, results of which are shown in Table 2. Further, the relationship between pressing pressure and filling rate and relationship between the filling rate and collected charge amount are shown in FIGS. 4 and 5 respectively. In Table 2, the data in the row of pressing pressure=0 are data of Comparative Example 1 produced without subjected to thermal compression.

TABLE 2

| Pressing pressure | Filling Rate | Collected Charge |
|---|---|---|
| (kg/cm²) | (%) | Amount |
| — | 35 | 220 |
| 62 | 38 | 700 |
| 126 | 39 | 1500 |
| 210 | 41 | 2800 |
| 308 | 45 | 3100 |
| 499 | 49 | 2427 |
| 926 | 52 | 1829 |
| 1462 | 56 | 1385 |
| 1642 | 58 | 579 |

As is clear from Table 2, the thermal compression improves the filling rate. This might be the result that the contact between

Bi₁₂SiO₂₀ particles is increased by the thermal compression and the probability that the particles are linked together is increased. In addition, the graph in FIG. 4 shows that the contact is increased as the pressing pressure of thermal compression is increased, whereby the collected charge amount is increased. In the mean time, it is known from FIG. 5 that an excessively high pressing pressure causes collected charge amount to be reduced although the filling rate remains high. This might be due to that the particles are destroyed (increased defects, crystal break, and the like) and the amount of charges generated in the radiation photoconductive layer by radiation and conductivity of the layer are reduced.

What is claimed is:

1. A method for manufacturing a radiation detector having an active matrix layer in which multiple switching elements are arranged and a radiation photoconductive layer that generates a charge in response to radiation of an electromagnetic wave representing image information and arranged such that the charge is read out by the active matrix layer, the method comprising the steps of:
forming a coating film by applying, on a tentative support, a dispersion solution in which at least an inorganic semiconductor particle and a binder are dispersed;
forming the radiation photoconductive layer by subjecting the coating film to thermal compression; and
joining the radiation photoconductive layer to the active matrix layer.

2. The method of claim 1, wherein a pressing pressure at the time of the thermal compression is in the range from 100 to 2000 kg/cm².

3. The method of claim 1, wherein the dispersion solution includes a charge transport material.

4. The method of claim 2, wherein the dispersion solution includes a charge transport material.

5. The method of claim 1, wherein an undercoating layer is provided on the thermo-compressed radiation photoconductive layer.

6. The method of claim 2, wherein an undercoating layer is provided on the thermo-compressed radiation photoconductive layer.

7. The method of claim 3, wherein an undercoating layer is provided on the thermo-compressed radiation photoconductive layer.

8. The method of claim 4, wherein an undercoating layer is provided on the thermo-compressed radiation photoconductive layer.

9. The method of claim 1, wherein the radiation photoconductive layer is joined to the active matrix layer after an undercoating layer is provided on the active matrix layer.

10. The method of claim 2, wherein the radiation photoconductive layer is joined to the active matrix layer after an undercoating layer is provided on the active matrix layer.

11. The method of claim 3, wherein the radiation photoconductive layer is joined to the active matrix layer after an undercoating layer is provided on the active matrix layer.

12. The method of claim 4, wherein the radiation photoconductive layer is joined to the active matrix layer after an undercoating layer is provided on the active matrix layer.

13. The method of claim 5, wherein the undercoating layer is a hole injection blocking layer.

14. The method of claim 6, wherein the undercoating layer is a hole injection blocking layer.

15. The method of claim 7, wherein the undercoating layer is a hole injection blocking layer.

16. The method of claim 8, wherein the undercoating layer is a hole injection blocking layer.

17. The method of claim 9, wherein the undercoating layer is a hole injection blocking layer.

18. The method of claim 10, wherein the undercoating layer is a hole injection blocking layer.

19. The method of claim 11, wherein the undercoating layer is a hole injection blocking layer.

20. The method of claim 12, wherein the undercoating layer is a hole injection blocking layer.
